(19) United States
(12) Patent Application Publication
(10) Pub. No.: US 2011/0151619 A1
(43) Pub. Date: Jun. 23, 2011

(54) METHOD OF FORMING METAL OXIDE FILM AND APPARATUS FOR FORMING METAL OXIDE FILM

(75) Inventors: Hiroyuki Orita, Tokyo (JP); Akio Yoshida, Tokyo (JP); Masahisa Kogura, Tokyo (JP); Takahiro Shirahata, Tokyo (JP); Syuji Tanaka, Tokyo (JP)

(73) Assignee: TOSHIBA MITSUBISHI-ELECTRIC INDUSTRIAL SYS. CORP., TOKYO (JP)

(21) Appl. No.: 13/059,128

(22) PCT Filed: Sep. 24, 2008
(86) PCT No.: PCT/JP08/67164

§ 371 Date: Feb. 15, 2011

(51) Int. Cl. H01L 21/36; H01L 21/443

(52) U.S. Cl. 438/104; 438/609; 257/E21.461; 257/E21.478

(57) ABSTRACT

A method of forming a metal oxide film, which can lower a temperature of a heat treatment of a substrate and also can form a metal oxide film having a low resistance value without limiting the kind of the metal oxide film to be formed. The method of forming a metal oxide film includes (A) converting a solution containing a metal into mist, (B) heating a substrate, and (C) supplying the solution converted into mist, and ozone to a first main surface of the substrate under heating.

### TECHNICAL FIELD

The present invention relates to a method of forming a metal oxide film in which the metal oxide film is formed on a substrate, and an apparatus for forming a metal oxide film, which is capable of carrying out the method of forming a metal oxide film.

### BACKGROUND ART

In the fields of solar batteries, light emitting devices and touch panels, a metal oxide film is formed on a substrate. As techniques for forming the metal oxide film on the substrate, those disclosed in Patent Documents 1, 2 and 3 conventionally exist.

In the technique according to Patent Document 1, by bringing a solution containing a metal salt or a metal complex dissolved therein into contact with a heated substrate, a metal oxide film is formed on the substrate. Herein, the solution contains at least one of an oxidizing agent and a reducing agent.

In the technique according to Patent Document 2, a tetrabutyltin or tin tetrachloride solution containing hydrogen peroxide as an oxidizing agent added therein is thermally decomposed by spraying over a preheated substrate. After waiting for recovery of a substrate temperature lowered by spraying the solution, spraying of the solution is repeatedly carried out. Whereby, a tin oxide thin film is grown on a surface of the substrate.

In the technique according to Patent Document 3, a thin film material dissolved in a volatile solvent is sprayed intermittently toward a heat-retained substrate from above to form a transparent conductive film on a surface of a substrate. Herein, intermittent spraying is high-speed pulse intermittent spraying in which a spraying time per one spraying is a hundred milliseconds or less.

Patent Document 1: Japanese Patent Application Laid-Open No. 2007-109406

Patent Document 2: Japanese Patent Application Laid-Open No. 2002-146536

Patent Document 3: Japanese Patent Application Laid-Open No. 2007-144297

### DISCLOSURE OF THE INVENTION

### Problems to be Solved by the Invention

However, in Patent Document 1, it is necessary to heat the substrate to 300° C. or higher, and the kind of the substrate to be used is limited and the substrate is damaged by heat. Also, there is a problem that the metal oxide film (zinc oxide film) formed by the technique according to Patent Document 1 has high electric resistance value.

In Patent Document 2, there is a problem that a high-temperature heat treatment of the substrate is required similarly to the above case, and there is also a problem that the kind of a metal oxide film to be formed is limited since acidic hydrogen peroxide is used as an additive.

In Patent Document 3, similarly to the above case, there is a problem that a high-temperature heat treatment of the substrate is required similarly to the above case.

Thus, an object of the present invention is to provide a method of forming a metal oxide film, which can lower a temperature of a heat treatment of a substrate and also can form a metal oxide film having a low resistance value without limiting the kind of the metal oxide film to be formed; and an apparatus for forming a metal oxide film, which can carry out the film formation method.

### Means for Solving the Problems

To achieve the above object, according to a first aspect of the present invention, a method of forming a metal oxide film includes the steps of (A) converting a solution containing a metal into mist, (B) heating a substrate, and (C) supplying the solution converted into mist in the step (A) and ozone to a first main surface of the substrate in the step (B).

According to a second aspect of the present invention, a method of forming a metal oxide film includes the steps of (V) converting a solution containing a metal into mist, (W) supplying the solution converted into mist in the step (V), and oxygen or ozone to a first main surface of a substrate, and (X) irradiating the oxygen or the ozone with ultraviolet rays.

According to a third aspect of the present invention, a method of forming a metal oxide film includes the steps of (V) converting a solution containing a metal into mist, (W) supplying the solution converted into mist in the step (V), and oxygen or ozone to a first main surface of a substrate, and (W) converting the oxygen or the ozone into plasma.

According to a fourth aspect of the present invention, the method of forming a metal oxide film according to any one of claims 1 to 15 is carried out by an apparatus for forming a metal oxide film.

### EFFECTS OF THE INVENTION

According to the first and fourth aspects of the present invention, since a metal oxide film is formed while adding ozone, ozone and active oxygen produced by decomposition of ozone due to heat or the like are rich in reactivity, thus promoting decomposition and oxidation of a material compound in a solution. Whereby, a metal oxide film can be formed on a substrate even in a state of low-temperature heating. Since it is not necessary to use an acid or an alkali for the solution, the kind of the metal oxide film to be formed is not limited and also it becomes possible to form a zinc oxide film having poor resistance to an acid or an alkali. Furthermore, the metal oxide film formed by the addition of ozone contains large crystal grains, resulting in a texture structure. Therefore, the metal oxide film to be formed has low sheet resistance and also has an excellent light confinement effect.

According to the second and third aspects of the present invention, since ozone (or oxygen) is supplied toward a substrate and the ozone (or oxygen) is irradiated with ultraviolet rays or converted into plasma, it is possible to promote, in addition to the above effect, the reaction for formation of a metal oxide film on a first main surface of a substrate. It also becomes possible to omit a heat treatment to the substrate, or to suppress a heating temperature in the heat treatment.

Objects, features, aspects and advantages of the present invention will become more apparent from the following detailed description taken in conjunction with the accompanying drawings.

### BRIEF DESCRIPTION OF THE DRAWINGS

FIG. 1 is a diagram showing a constitution of an apparatus for forming a metal oxide film according to an embodiment 1.

FIG. 2 is a view showing an image obtained by observation using an electron microscope of a metal oxide film formed under film formation conditions without the addition of ozone.

FIG. 3 is a view showing an image obtained by observation using an electron microscope of a metal oxide film formed by a film formation method according to the embodiment 1.

FIG. 4 is a graph for explaining the effects of the invention according to the embodiment 1.

FIG. 5 is a view showing an image obtained by observation using an electron microscope of a metal oxide film formed under film formation conditions without the addition of ozone.

FIG. 6 is a diagram showing a constitution of an apparatus for forming a metal oxide film according to an embodiment 2.

FIG. 7 is a diagram showing a constitution of an apparatus for forming a metal oxide film according to an embodiment 3.

FIG. 8 is a diagram showing another constitution example of an apparatus for forming a metal oxide film according to the embodiment 3.

FIG. 9 is a diagram showing a constitution of an apparatus for forming a metal oxide film according to an embodiment 4.

FIG. 10 is a diagram showing another constitution example of an apparatus for forming a metal oxide film according to the embodiment 4.

### BEST MODE FOR CARRYING OUT THE INVENTION

### Embodiment 1

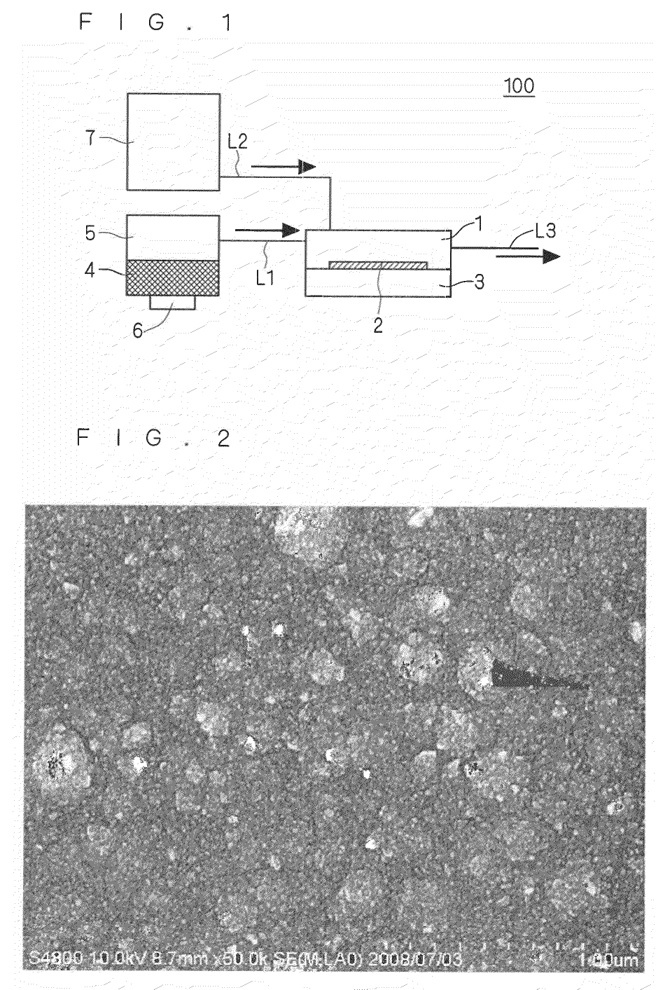

FIG. 1 is a diagram showing a schematic constitution of an apparatus for forming a metal oxide film according to the present embodiment.

As shown in FIG. 1, an apparatus 100 for forming a metal oxide film according to the embodiment 1 is composed of a reaction vessel 1, a heating device 3, a solution container 5, a misting device 6 and an ozone generator 7.

In the film formation apparatus 100, a spray pyrolysis method, a pyrosol method, a mist accumulation method or the like is carried out. In other words, in the film formation apparatus 100, by spraying a predetermined solution converted into mist to a first main surface a substrate 2, a predetermined metal oxide film can be formed on the first main surface of the substrate 2.

In a state where the substrate 2 is placed on the heating device 3, a metal oxide film is formed on the first main surface of the substrate 2 by a predetermined reaction inside the reaction vessel 1. A second main surface of the substrate 2 is placed on the heating device 3. As is apparent from the above description, the first main surface of the substrate 2 referred to in the present description is a main surface of the substrate 2 on the side on which the metal oxide film is formed. To the contrary, the second main surface of the substrate 2 referred to in the present description is a main surface of the substrate 2 on the side to be placed on the heating device 3.

Herein, after controlling the pressure inside the reaction vessel 1 to an atmospheric pressure, the metal oxide film may be formed on the substrate 2 under the atmospheric pressure. Alternatively, while evacuating inside the reaction vessel 1 within a range from 0.0001 to 0.1 MPa, the metal oxide film may be formed on the substrate 2 under the reduced pressure environment.

It is possible to employ, as the substrate 2, a glass substrate, a flexible substrate such as a resin film, and a plastic substrate used in the fields of flat panel displays such as solar batteries, light emitting devices, touch panels and liquid crystal panels.

The heating device 3 is a heater or the like, and can heat the substrate 2 placed on the heating device 3. The heating device 3 is heated to a metal oxide film formation temperature by an external controller.

The solution container 5 is filled with a material solution (hereinafter referred to as a solution) 4 containing a metal salt, a metal complex or a metal alkoxide compound as a metal source dissolved therein. The metal contained in the solution 4 is at least any one among titanium (Ti), zinc (Zn), indium (In) and tin (Sn).

The solution 4 does not have to contain a dopant source described later. However, the solution 4 preferably contains, as the dopant source, at least any one of boron (B), nitrogen (N), fluorine (F), magnesium (Mg), aluminum (Al), phosphorus (P), chlorine (Cl), gallium (Ga), arsenic (As), niobium (Nb), indium (In) and antimony (Sb).

It is possible to employ, as a solvent of the solution 4, water, alcohols such as ethanol and methanol, and a mixed liquid of these liquids.

As the misting device 6, for example, an ultrasonic atomizer can be employed. The misting device 6, which is the ultrasonic atomizer, enables the solution 4 in the solution container 5 to convert into mist by applying ultrasonic wave to the solution 4 in the solution container 5. The solution 4 converted into mist is supplied toward the first main surface of the substrate 2 in the reaction vessel 1 through a path L1.

The ozone generator 7 can generate ozone. Ozone produced in the ozone generator 7 is supplied toward the first main surface of the substrate 2 in the reaction vessel 1 through a path L2 which is different from the path L1. In the ozone generator 7, for example, a high voltage is applied between parallel electrodes disposed in parallel and oxygen is passed through the electrodes, thereby decomposing oxygen molecules, resulting in bonding with other oxygen molecules, and thus ozone can be generated.

When ozone and the misty solution 4 are supplied into the reaction vessel 1, the ozone reacts with the solution 4 on the substrate 2 under heating to form a predetermined metal oxide film on the first main surface of the substrate 2. The metal oxide film to be formed is, for example, a transparent conductive film of indium oxide, zinc oxide, tin oxide or the like, although it varies depending on the kind of the solution 4. The ozone and the solution 4 remaining in the reaction vessel 1 without being reacted are always (continuously) discharged out of the reaction vessel 1 through a path L3.

The method of forming a metal oxide film according to the present embodiment will be described below.

In the solution container 5, the solution 4 is converted into mist by the misting device 6. The solution 4 converted into mist is supplied to the reaction vessel 1 through the path L1. Ozone is produced in the ozone generator 7. Ozone thus produced is supplied to the reaction vessel 1 through the path L2.

On the other hand, the substrate 2 placed on the heating device 3 is heated to a metal oxide film formation temperature by the heating device 3, and the temperature of the substrate 2 is maintained at the metal oxide film formation temperature.

Ozone and the misty solution 4 are supplied to the first main surface of the substrate 2 in a heated state. When the ozone and the misty solution 4 are contacted with the substrate 2 in the heated state, ozone is thermally decomposed to produce oxygen radicals and decomposition of the solution 4 is promoted by the oxygen radicals, and a predetermined metal oxide film is formed on the first main surface of the substrate 2.

Herein, the film formation step may be the step of supplying the solution 4 and ozone to the substrate 2 arranged under an atmospheric pressure to form a metal oxide film on the substrate 2. To the contrary, it may be the step of supplying the solution 4 and ozone to the substrate 2 arranged under a reduced pressure (for example, 0.0001 to 0.1 MPa) environment by separately providing a film formation apparatus 100 with a vacuum pump (not shown) capable of evacuating inside the reaction vessel 1 to form a metal oxide film on the substrate 2.

As described above, in the method of forming a metal oxide film according to the present embodiment, the solution 4 containing a metal salt or a metal complex or a metal alkoxide compound, as a metal source, dissolved therein is converted into mist. Furthermore, in the reaction vessel 1 in an atmosphere containing ozone, the misty solution 4 is contacted with the substrate 2 under heating.

Therefore, since ozone, and active oxygen produced by decomposition of ozone due to heat or the like are rich in reactivity, thus promoting decomposition and oxidation of a material compound in the solution 4. Whereby, a metal oxide film can be formed on the substrate 2 even in a state of low-temperature heating. For example, in the absence of ozone, it may be required to heat the substrate to about 500° C. in the case of forming the metal oxide film. In the present embodiment, as described later, the metal oxide film can be formed on the substrate 2 even in the case of heating the substrate to about 200° C.

Decomposition of ozone starts at about 200° C. (in other words, production of oxygen radicals from ozone starts at a heating temperature of 200° C.). Therefore, even when the heating temperature of the substrate 2 is about 200° C., a metal oxide film can be formed on the substrate 2. Commonly, 90% of ozone is decomposed at 350° C. in 3 seconds, and almost 100% of ozone is decomposed at 500° C. in about 0.5 to 0.6 seconds. Therefore, the heating temperature of the substrate 2 may be raised for the purpose of increasing a film formation speed of the metal oxide film.

Although ozone is used in the method of forming a metal oxide film according to the present embodiment, it is not necessary to use an acid or an alkali in the solution 4.

Therefore, the kind of the metal oxide film to be formed is not limited and it becomes possible to form a zinc oxide film having poor resistance to an acid or an alkali.

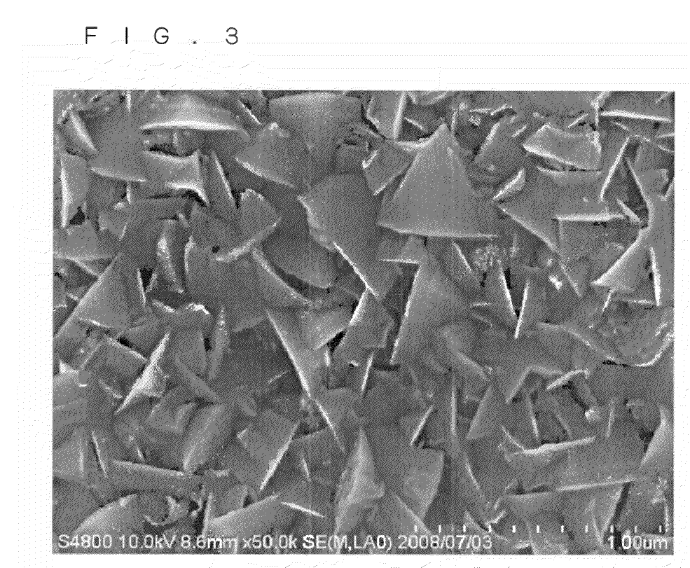

FIG. 2 is a view showing an image obtained by observation using an electron microscope of a metal oxide film formed by supplying a misty solution 4 on a substrate 2 without using ozone.

The metal oxide film of FIG. 2 shows a case where a substrate temperature is 300° C. In the case of forming the metal oxide film shown in FIG. 2, zinc acetate dihydrate was employed as a metal source contained in the solution 4 and a mixed liquid of methanol (90 ml) and water (10 ml) was used as a solvent of the solution 4. The concentration of the metal source in the solution 4 is 0.05 mol/L.

As is apparent from FIG. 2, the metal oxide film thus formed contains small crystal grains. Due to these small crystal grains, the metal oxide film shown in FIG. 2 has an increased sheet resistance value of 4.39×10⁵ Ω/□.

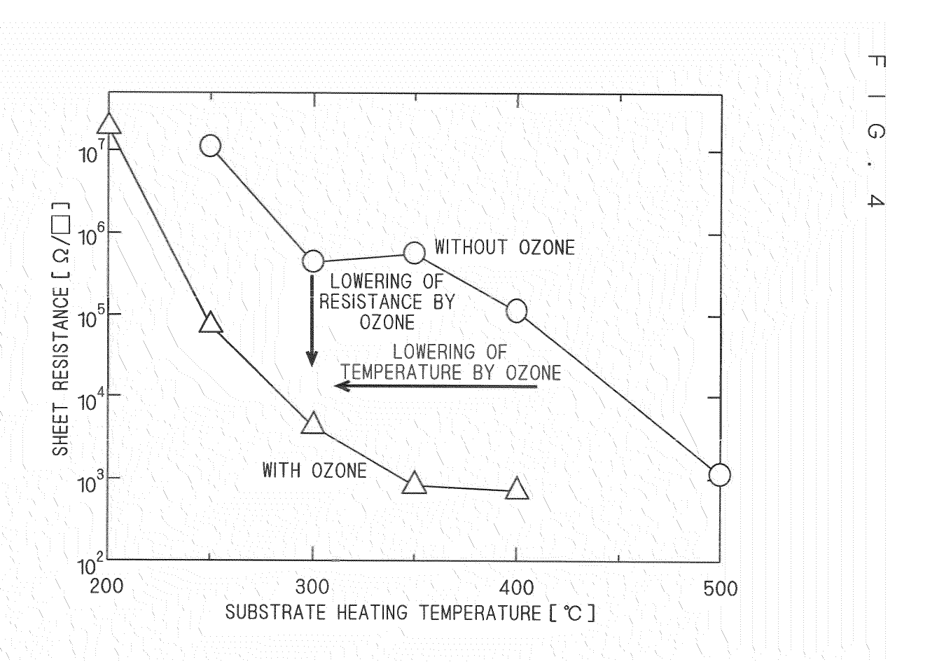

FIG. 3 is a view showing an image obtained by observation using an electron microscope of a metal oxide film formed by a method of forming a metal oxide film according to the present embodiment.

In the case of forming the metal oxide film shown in FIG. 3, the same film formation conditions as those of the metal oxide film shown in FIG. 2 are employed in a state where ozone is added (the substrate heating temperature is also the same: 300° C.). Herein, a supply concentration of ozone is 50 g/cm³. Furthermore, an ozone supply flow rate is 2 L/min.

As is apparent from FIG. 3, crystal grains of the metal oxide film formed by a film formation method according to the present embodiment are larger than those in the case of FIG. 2. Due to these large crystal grains, the metal oxide film shown in FIG. 3 has a decreased sheet resistance value of 4.36×10³ Ω/□.

FIG. 4 is an experiment example showing a relationship between the sheet resistance of a metal oxide film and the substrate heating temperature.

In FIG. 4, the symbol “◯” denotes an experiment data example in the case where no ozone was added, and the symbol “Δ” denotes an experiment data example in the case where ozone was added (in the case of the method according to the present embodiment). The horizontal axis of FIG. 4 denotes a substrate heating temperature (° C.), and the vertical axis of FIG. 4 denotes sheet resistance (Ω/□) of a metal oxide film.

As is apparent from FIG. 4, even when a metal oxide film having the same sheet resistance is obtained, it becomes possible to lower the substrate heating temperature by employing the method of forming a metal oxide film according to the present embodiment. When the same conditions of the substrate heating temperature are employed in the case where ozone is added and in the case where no ozone is added, sheet resistance of the metal oxide film to be formed is more lowered when the film formation method according to the present embodiment is employed.

In other words, as is apparent from the consideration of FIGS. 2 to 4, by employing the method of forming a metal oxide film according to the present embodiment, it becomes possible to lower the substrate heating temperature as a portion of film formation conditions, and to lower the resistance of the metal oxide film to be formed.

As is apparent from FIG. 3, each crystal grain has a texture structure. On the other hand, in the case of the metal oxide film formed in the absence of ozone, the crystal grain is rounded and does not have a texture structure as shown in FIG. 2.

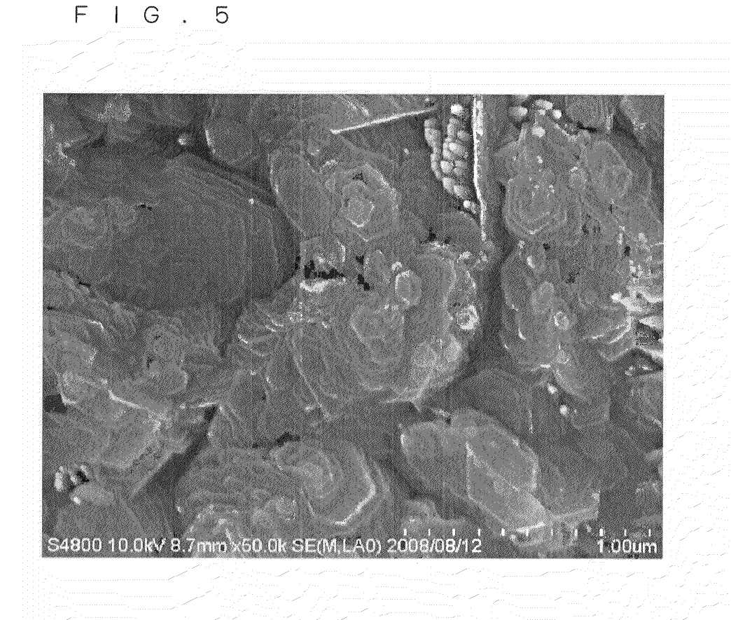

When the substrate heating temperature is raised in the absence of ozone, the crystal grain of the metal oxide film to be formed becomes large as shown in FIG. 5. Herein, the film formation conditions in FIG. 5 are the same as those of FIG. 2, except for the substrate heating temperature. The substrate heating temperature (=500° C.) of the film formation conditions in FIG. 5 is higher than that of the film formation conditions in FIG. 2.

As is apparent from enlargement of the size of the crystal grain, the sheet resistance of the metal oxide film formed in the absence of ozone when the substrate heating temperature is a high temperature is improved more than that of the metal oxide film formed when the substrate heating temperature is a low temperature. However, as is apparent from FIG. 5, it should be noted that the obtained crystal grain does not have a texture structure in the absence of ozone even if the substrate heating temperature is raised.

As described above, in the metal oxide film formed by adding ozone, the obtained crystal grain has a texture structure. Therefore, the metal oxide film formed by adding ozone exerts a higher light confinement effect than that in the case of the metal oxide film formed in the absence of ozone. Since the light confinement effect is improved as described above, it becomes possible to enhance photoelectric conversion efficiency of a solar battery by using the metal oxide film formed by adding ozone for the solar battery.

For example, a haze rate of the metal oxide film to be formed was compared by formation of a film with or without the addition of ozone at the substrate heating temperature of 300° C. Other conditions except for the above conditions are the same in both cases (with or without the addition of ozone). Herein, the haze rate (%) is represented by (amount of diffuse transmitted light/amount of entire transmitted light)×100. A higher haze rate means a higher light confinement effect.

It was confirmed that the haze rate of the case of the addition of ozone increases by about 10 times compared with the case of adding no ozone.

In the case of the film formation method according to the present embodiment, it was confirmed that even when the substrate heating temperature is a low temperature of about 250° C., the size of the obtained crystal grain decreases, but a metal oxide film containing crystal grains having a texture structure is formed on the substrate 2. It is considered that formation of the metal oxide film containing crystal grains having a texture structure on the substrate 2 is theoretically possible even when the substrate heating temperature is 250° C. or lower.

It is possible to form a transparent conductive film on the substrate 2 by employing, as a metal source contained in the solution 4, at least any one among titanium, zinc, indium and tin.

In a state where the solution 4 contains titanium, zinc, indium and tin, the solution 4 may contain, as a dopant, at least any one of boron, nitrogen, fluorine, magnesium, aluminum, phosphorus, chlorine, gallium, arsenic, niobium, indium and antimony.

Depending on the kind of the dopant, the metal oxide film (transparent conductive film) serving as an N-type semiconductor can be transformed into a more electron excess state. In this case, electric resistance of the metal oxide film (transparent conductive film) to be formed can be more lowered. Depending on the kind of the dopant, the metal oxide film can be allowed to serve as a P-type semiconductor. In the metal oxide film of the P-type semiconductor, holes serve as carriers and can impart conductivity, and utility value for the light emitting device increases, rather than for the transparent conductive film.

As described above, after controlling the pressure inside the reaction vessel 1 to an atmospheric pressure, a metal oxide film may be formed on the substrate 2 under the atmospheric pressure.

Whereby, the constitution such as a vacuum device can be omitted, and therefore costs of the film formation apparatus 100 can be reduced.

To the contrary, as described above, it is possible to provide a vacuum pump or the like capable of evacuating inside the reaction vessel 1. While evacuating inside the reaction vessel 1 within a range from 0.0001 to 0.1 MPa, a metal oxide film may be formed on the substrate 2 under the reduced pressure environment.

Whereby, costs of the film formation apparatus 100 increase, but it becomes possible to form a metal oxide film with better quality on the substrate 2 compared with a metal oxide film formed under an atmospheric pressure.

Also, as is apparent from the constitution of FIG. 1, the solution 4 and ozone are supplied to the substrate 2 through different paths. In the constitution of FIG. 1, the solution 4 is supplied toward the substrate 2 in the reaction vessel 1 through the path L1. On the other hand, ozone is supplied toward the substrate 2 in the reaction vessel 1 through the path L2.

As described above, by supplying the solution 4 and ozone to the substrate 2 through different paths L1, L2, it is possible to limit the position where ozone and the solution 4 are mixed with each other to only the reaction vessel 1 (a range where the substrate 2 is disposed). In other words, it is possible to prevent the solution 4 and ozone from mixing with each other in a path of the supply process. Therefore, it is possible to limit the range of the reaction between the solution 4 and ozone to only the range where the substrate 2 is disposed, and to improve the reaction efficiency at the substrate 2. By mixing the solution 4 and ozone with each other in the supply process, the solution 4 may react with ozone to produce an unintended reaction product in a vapor phase before arrival to the substrate. The production of the unintended reaction product may prevent the growth of a film on a surface of the substrate (deterioration in film quality and decrease in film formation rate by accumulation of the unintended reaction product). Herein, the production of the unintended reaction product can be suppressed by supplying the solution 4 and ozone to the substrate 2 through the different paths L1, L2.

The film formation apparatus 100 may be further provided with a controller (not shown) capable of performing the following control. The controller performs the control so that the solution 4 converted into mist and ozone are supplied to the substrate 2 in the reaction vessel 1 simultaneously or separately at predetermined timings.

By simultaneously supplying the solution 4 converted into mist and ozone to the substrate 2 in the reaction vessel 1, ozone reactivity (oxidizability) in the reaction vessel 1 can be sufficiently utilized.

On the other hand, by separately supplying the solution 4 converted into mist and ozone to the substrate 2 in the reaction vessel 1, the reaction between ozone and the solution 4 at a position other than the surface of the substrate can be suppressed.

By separately supplying the solution 4 converted into mist and ozone to the substrate 2 in the reaction vessel 1, it becomes impossible to sufficiently utilize ozone reactivity (oxidizability) in the reaction vessel 1. However, characteristics of the metal oxide film to be formed are improved by supplying ozone while heating the substrate 2 (for example, improvement in crystallinity and improvement in electric resistance depending on mobility and carrier concentration).

### Embodiment 2

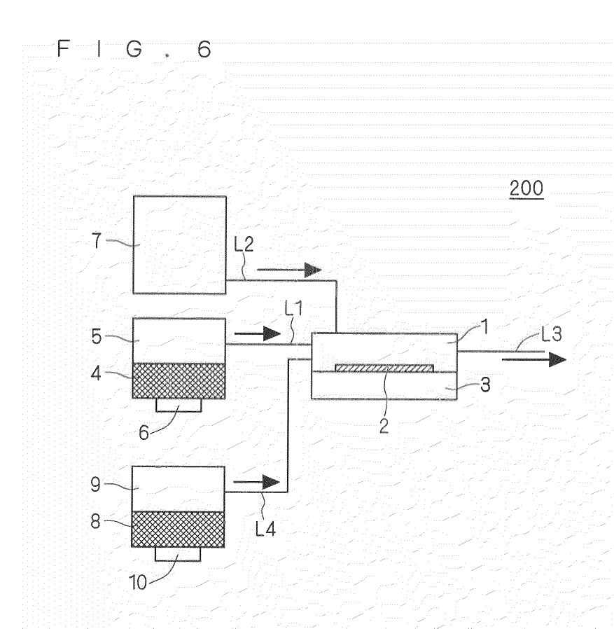

FIG. 6 is a diagram showing a schematic constitution of an apparatus for forming a metal oxide film according to the present embodiment.

As shown in FIG. 6, concerning an apparatus 200 for forming a metal oxide film according to the embodiment 2, a solution container 9 and the misting device 10 are separately added to the apparatus 100 for forming a metal oxide film according to the embodiment 1.

The solution container 9 is filled with a solution 8 which is different from the solution 4 with which the solution container 5 is filled. As shown in FIG. 6, the misting device 10 is arranged in the solution container 9 and converts the solution 8 in the solution container 9 into mist. Herein, the misty solution 8 is sprayed over the substrate 2 in the reaction vessel 1 through a path L4 different from the path L1 and the path L2.

The film formation apparatus 200 has the same constitution as that of the film formation apparatus 100, except for the separately added constitution, and the same numerals are used for the same constitutions. Concerning the description of the same constitution and the operation of the constitution, refer to the embodiment 1.

The film formation apparatus 200 converts the solution 4 into mist, and also converts a solution 8 which is different from the solution 4 into mist. The film formation apparatus 200 is provided with a controller (not shown), and the solution 4 and the solution 8 are supplied to the substrate 2 in the following manner in accordance with control of the controller.

In other words, in accordance with control of the controller, the different solutions 4, 8 converted into mist may be simultaneously supplied to the substrate 2. In accordance with control of the controller, the different solutions 4, 8 converted into mist may also be supplied to the substrate 2 in a predetermined order (the solution 8 is supplied after supplying the solution 4, and thus supply of the solutions 4, 8 is completed, or the solution 4 converted into mist is supplied after supplying the solution 8 converted into mist, and thus supply of the solutions 4, 8 is completed). In accordance with control of the controller, the different solutions 4, 8 converted into mist may be supplied to the substrate 2 alternately and repeatedly (for example, supply of the solution 4→supply of the solution 8→supply of the solution 4→supply of the solution 8→completion of supply of the solutions 4, 8).

By employing the film formation apparatus 200 according to the present embodiment, various metal oxide films having a single- or multi-layered structure can be formed on the substrate 2. It is also possible to select a solvent which is suited for each material. For example, although zinc acetate as a metal source is easily soluble in water and alcohols, aluminum acetylacetonate as a dopant source has low solubility in water and alcohols. Therefore, it may be impossible to satisfactorily set the concentration when the solvent is the same as that for zinc acetate. However, it is possible to separately use a solvent (for example, acetylacetone) in which aluminum acetylacetonate is easily dissolved by using separate solution containers.

In the constitution of FIG. 6, only two solution containers 5, 9 are prepared and the respective solution containers 5, 9 accommodate different solutions 4, 8. The respective solutions 4, 8 are converted into mist by the respective misting devices 6, 10.

However, there may be employed such a constitution that the number of solution containers is three or more and the respective solution containers accommodate different solutions, and the respective solutions are converted into mist by each misting device arranged in each solution container.

Also in the case of the constitution that the number of the solution containers is three or more, different solutions converted into mist may be simultaneously supplied to the substrate 2 in accordance with control of the controller (not shown). Also, different solutions converted into mist may be separately supplied to the substrate 2 in a predetermined order in accordance with control of the controller. In the case of the constitution that the number of the solution containers is three or more, it is desired that each solution is supplied toward the substrate 2 in the reaction vessel 1 from the solution containers through different paths.

In the case of the constitution that two or more kinds of solutions are supplied, two or more kinds of solutions and ozone are supplied toward the substrate 2 disposed in the reaction vessel 1.

In this case, in accordance with control of the controller (not shown), while ozone is always supplied, different solutions may be separately supplied in a predetermined order. In accordance with control of the controller (not shown), different solutions may be separately supplied in a predetermined order and, after temporarily stopping supply of the solutions every time supply of the solutions is switched, ozone may be supplied (for example, supply of first solution→supply of ozone→supply of second solution→supply of ozone→supply of third solution→supply of ozone). Herein, in any of the supply aspects, it is desired that each solution and ozone are supplied toward the substrate 2 in the reaction vessel 1 from the solution containers or the ozone generator 7 through different paths.

Herein, in the case of supplying two kinds of solutions and ozone, the atmosphere inside the reaction vessel 1 in which the substrate 2 is arranged may be an atmospheric pressure or a reduced pressure environment, as described in the embodiment 1.

### Embodiment 3

FIG. 7 is a diagram showing a schematic constitution of an apparatus for forming a metal oxide film according to the present embodiment.

As shown in FIG. 7, concerning an apparatus 300 for forming a metal oxide film according to the embodiment 3, an ultraviolet generator 11 and an ultraviolet transmission window 12 are separately added to the apparatus 100 for forming a metal oxide film according to the embodiment 1.

The ultraviolet generator 11 is a portion where ultraviolet rays (wavelength: about 10 nm to 400 nm) are generated. Examples of the ultraviolet generator 11 capable of generating ultraviolet rays include a mercury lamp and an excimer lamp. Ultraviolet rays having wavelengths of 254 nm and 185 nm are generated from a low-pressure mercury lamp. When xenon, krypton and argon are used as cooling media, ultraviolet rays having wavelengths of 172 nm, 146 nm and 126 nm are respectively generated from an excimer lamp.

This kind of the ultraviolet generator 11 is composed of a discharge tube, an electrode disposed around the discharge tube, and a power supply which apply an AC voltage or a pulse voltage to the electrode through an electric supply line. An AC voltage or a pulse voltage is applied to the electrode by the power supply. Whereby, discharge can be generated inside the discharge tube, and ultraviolet rays are generated as a result of the discharge.

The ultraviolet generator 11 is arranged above the reaction vessel 1, in other words, arranged facing a first main surface, which is the surface on which the metal oxide film is formed, of the substrate 2.

As shown in FIG. 7, the ultraviolet transmission window 12, which transmits ultraviolet rays emitted from the ultraviolet generator 11, is provided at the upper portion of the reaction vessel 1. Specifically, the ultraviolet transmission window 12 is arranged at a portion of the reaction vessel 1 between the ultraviolet generator 11 and the substrate 2.

The ultraviolet transmission window 12 is made from a material which transmits ultraviolet rays. For example, the ultraviolet transmission window 12 is made from materials such as magnesium fluoride, calcium fluoride, barium fluoride, lithium fluoride, sodium fluoride, potassium fluoride, quartz and sapphire.

The film formation apparatus 300 has the same constitution as that of the film formation apparatus 100, except for the separately added constitution, and the same numerals are used for the same constitutions. Concerning the description of the same constitution and the operation of the constitution, refer to the embodiment 1.

The solution 4 converted into mist by the misting device 6 is supplied to the first main surface of the substrate 2 (surface on which a metal oxide film is formed) arranged in the reaction vessel 1 through the path L1. On the other hand, ozone produced by the ozone generator 7 is supplied to the first main surface of the substrate 2 arranged in the reaction vessel 1 through the path L2.

When the solution 4 and ozone are supplied, the substrate 2 is heated by the heating device 3 in the reaction vessel 1, and also the inside of the reaction vessel 1 above the substrate 2 is irradiated with ultraviolet rays produced by the ultraviolet generator 11 through the ultraviolet transmission window 12.

As a result of irradiation of ultraviolet rays, ozone supplied to the reaction vessel 1 is irradiated with ultraviolet rays. Whereby, oxygen radicals are produced from ozone in the reaction vessel 1.

Herein, in order to decompose ozone into oxygen radicals, it is desired to irradiate ozone with ultraviolet rays having a wavelength of 300 nm or less (particularly, a wavelength of about 254 nm). In order to activate the metal oxide film formed on the substrate 2, it is desired to irradiate ozone with ultraviolet rays having a wavelength of 400 nm or less (particularly, a wavelength of about 300 nm).

As described above, the apparatus 300 for forming a metal oxide film according to the present embodiment is provided with the ultraviolet generator 11 and the ultraviolet transmission window 12 which transmits ultraviolet rays. Also, the inside of the reaction vessel 1 to which ozone and the solution 4 are supplied is irradiated with ultraviolet rays.

Therefore, ozone is decomposed into oxygen radicals by irradiation with the ultraviolet rays, thus making it possible to promote the reaction for formation of a metal oxide film in the reaction vessel 1 (more specifically, on the first main surface of the substrate 2).

Since ozone to be supplied to the reaction vessel 1 is decomposed into oxygen radicals by irradiation with ultraviolet rays, it is possible to omit the heating device 3 for heating the substrate 2 in the film formation apparatus 300 shown in FIG. 7. This is because a metal oxide film is formed on the substrate 2 at about normal temperature (room temperature) by introducing the constitution of irradiation with ultraviolet rays.

However, the arrangement of the heating device 3 in the film formation apparatus 300 has the following advantage. In other words, like the constitution of FIG. 7, the heating device 3 is provided and the substrate 2 is heated to about 100° C., and then ozone is supplied and the ozone is irradiated with ultraviolet rays. Whereby, it is possible to further promote the reaction for formation of a metal oxide film on the substrate 2, compared with the constitution in which the heating device 3 is not provided.

In the present embodiment, since the reaction vessel 1 is provided with the constitution of irradiation with ultraviolet rays, oxygen may be supplied to the reaction vessel 1 in place of ozone. In other words, it is not necessary to generate ozone by the ozone generator 7, and oxygen may be supplied to the first main surface of the substrate 2 in the reaction vessel 1 through the path L2, followed by irradiation of oxygen supplied to the reaction vessel 1 with ultraviolet rays. Herein, together with oxygen, the misty solution 4 is supplied to the first main surface of the substrate 2 in the reaction vessel 1 through the path L1.

Oxygen radicals are produced from oxygen by irradiating oxygen with ultraviolet rays. Herein, in order to decompose oxygen into oxygen radicals, it is desired to irradiate oxygen with ultraviolet rays having a wavelength of 243 nm or less (particularly, a wavelength of about 172 nm).

Also in the present embodiment, based on control of a controller (not shown), the solution 4 converted into mist and ozone (or oxygen) are supplied to the reaction vessel 1 simultaneously or separately. Also in the present embodiment, it is desired to supply the solution 4 converted into mist and ozone (or oxygen) to the reaction vessel 1 through the different paths L1, L2. Furthermore, the solution 4 converted into mist and ozone (or oxygen) may be supplied to the substrate 2 arranged under an atmospheric pressure, or to the substrate 2 arranged under a reduced pressure (for example, 0.0001 to 0.1 MPa) environment.

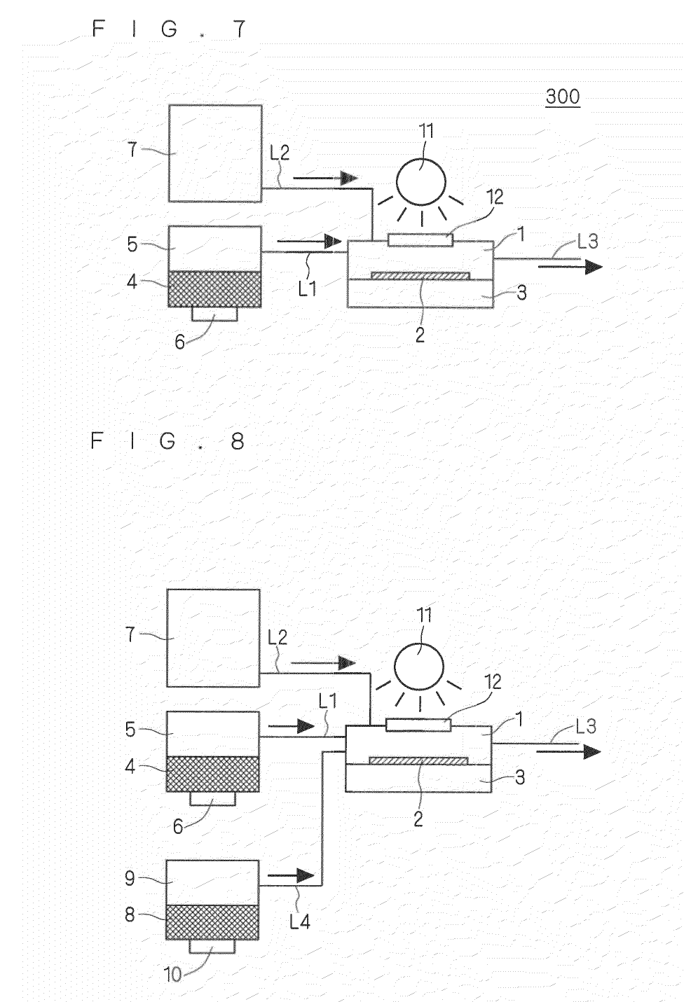

In the above description, mention was made about the constitution in which the ultraviolet generator 11 and the ultraviolet transmission window 12 are separately added to the apparatus 100 for forming a metal oxide film according to the embodiment 1. However, there may be employed the constitution in which the ultraviolet generator 11 and the ultraviolet transmission window 12 are separately added to the film formation apparatus capable of supplying two or more kinds of solutions described in the embodiment 2 (see FIG. 8).

In the constitution shown in FIG. 8, as described in the embodiment 2, the different solutions 4, 8 converted into mist may be simultaneously supplied to the substrate 2 under control of a controller (not shown). Under control of the controller (not shown), the different solutions 4, 8 converted into mist may be separately supplied to the substrate 2 in a predetermined order. Also in these supply aspects, as described in the embodiment 2, it is desired that the respective solutions 4, 8 are supplied toward the substrate 2 in the reaction vessel 1 from the solution containers 5, 9 through the different paths L1, L4.

In the constitution example of FIG. 8, as described in the embodiment 2, while ozone (or oxygen) is always supplied under control of a controller (not shown), the different solutions 4, 8 converted into mist may be separately supplied in a predetermined order. Alternatively, under control of a controller (not shown), the different solutions 4, 8 converted into mist may be separately supplied in a predetermined order and, after temporarily stopping supply of the solutions 4, 8 every time supply of the solutions 4, 8 is switched, ozone (or oxygen) may be supplied (for example, supply of the solution 4→supply of ozone (or oxygen)→supply of the solution 8→supply of ozone (or oxygen)).

Herein, in any of the supply aspects described above, it is desired that the respective solutions 4, 8 and ozone (or oxygen) are supplied toward the substrate 2 in the reaction vessel 1 through the different paths L1, L2, L4.

### Embodiment 4

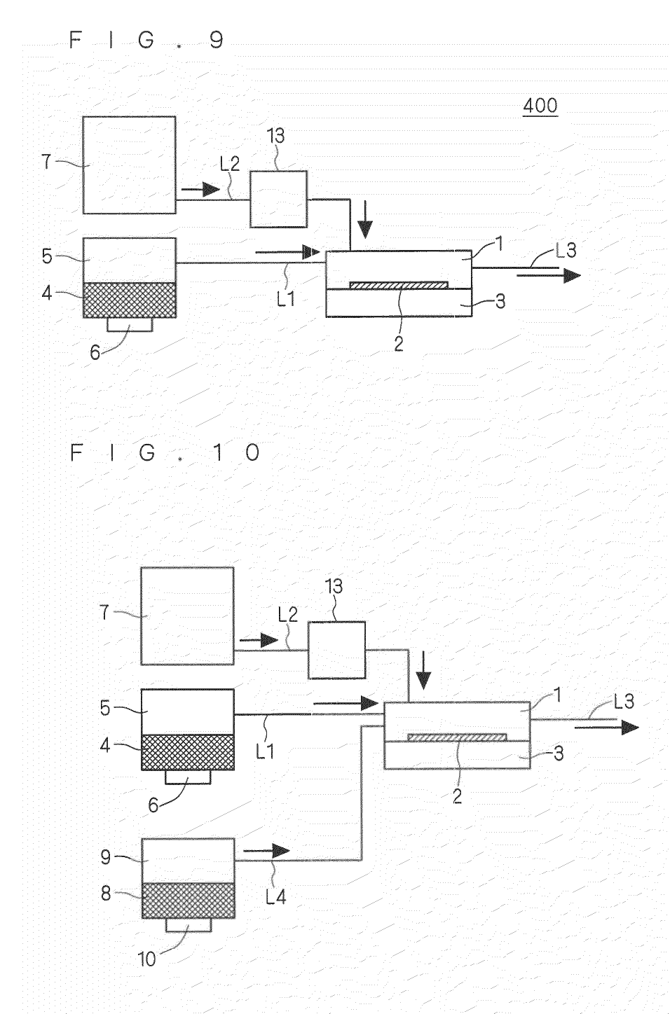

FIG. 9 is a diagram showing a schematic constitution of an apparatus for forming a metal oxide film according to the present embodiment.

As shown in FIG. 9, concerning an apparatus 400 for forming a metal oxide film according to the embodiment 4, a plasma generator 13 is separately added to the apparatus 100 for forming a metal oxide film according to the embodiment 1.

The plasma generator 13 is provided on the way of the path L2 arranged between the ozone generator 7 and the reaction vessel 1. In the plasma generator 13, two electrodes are provided at a predetermined distance. When ozone is supplied between the electrodes to which a high frequency voltage is applied, the ozone is converted into plasma to produce oxygen radicals. Oxygen radicals produced in the plasma generator 13 are supplied to the reaction vessel 1 through the path L2.

The film formation apparatus 400 has the same constitution as that of the film formation apparatus 100, except for the separately added constitution, and the same numerals are used for the same constitutions. Concerning the description of the same constitution and the operation of the constitution, refer to the embodiment 1.

The solution 4 converted into mist by the misting device 6 is supplied to the first main surface of the substrate 2 (surface on which a metal oxide film is formed) arranged in the reaction vessel 1 through the path L1. On the other hand, ozone produced in the ozone generator 7 is decomposed into oxygen radicals in the plasma generator 13 on the way through the path L2, and then supplied to the first main surface of the substrate 2 arranged in the reaction vessel 1.

When the solution 4 and ozone (more specifically, oxygen radicals produced in the plasma generator 13) are supplied, the substrate 2 is heated by the heating device 3 in the reaction vessel 1.

Herein, the plasma generator 13 may be a device for converting ozone into plasma to produce oxygen radicals, and the position where the plasma generator 13 is arranged is not particularly limited to the constitution of FIG. 9. For example, it may be arranged just proximal to the reaction vessel 1 on the path L2, and the plasma generator 13 may be arranged in the reaction vessel 1.

As described above, the apparatus 400 for forming a metal oxide film according to the present embodiment is provided with the plasma generator 13. Also, ozone to be supplied to the reaction vessel 1 is decomposed in the plasma generator 13.

Therefore, ozone is decomposed into oxygen radicals by the plasma generator 13, thus making it possible to promote the reaction for formation of a metal oxide film in the reaction vessel 1 (more specifically, on the first main surface of the substrate 2).

Since ozone to be supplied toward the reaction vessel 1 from the ozone generator 7 is decomposed into oxygen radicals by the plasma generator 13, it is possible to omit the heating device 3 for heating the substrate 2 in the film formation apparatus 400 shown in FIG. 9. This is because a metal oxide film is formed even on the substrate 2 at about normal temperature (room temperature) by introducing the plasma generator 13.

However, the arrangement of the heating device 3 in the film formation apparatus 400 has the following advantage. In other words, like the constitution of FIG. 9, the heating device 3 is provided and the substrate 2 is heated to about 100° C., and then ozone is supplied and the ozone is converted into plasma using the plasma generator 13. Whereby, it is possible to further promote the reaction for formation of a metal oxide film on the substrate 2, compared with the constitution in which the heating device 3 is not provided.

In the present embodiment, because of being provided with the plasma generator 13 capable of converting ozone into plasma, oxygen may be supplied toward the reaction vessel 1 in place of ozone. In other words, it is not necessary to generate ozone by the ozone generator 7, and oxygen may be supplied toward the first main surface of the substrate 2 in the reaction vessel 1 through the path L2 and the oxygen maybe converted into plasma in the reaction vessel 1 or on the way of the path L2. Oxygen radicals are produced from oxygen by converting oxygen into plasma inside the plasma generator 13. Herein, together with oxygen, the misty solution 4 is supplied to the first main surface of the substrate 2 in the reaction vessel 1 through the path L1.

Also in the present embodiment, the solution 4 converted into mist and ozone (or oxygen) are supplied to the reaction vessel 1 simultaneously or separately. Also in the present embodiment, it is desired to supply the solution 4 converted into mist and ozone (or oxygen) to the reaction vessel 1 through the different paths L1, L2. Furthermore, the solution 4 converted into mist and ozone (or oxygen) may be supplied to the substrate 2 arranged under an atmospheric pressure, or to the substrate 2 arranged under a reduced pressure (for example, 0.0001 to 0.1 MPa) environment.

In the above description, mention was made about the constitution in which the plasma generator 13 is separately added to the apparatus 100 for forming a metal oxide film according to the embodiment 1. However, there may be employed the constitution in which the plasma generator 13 is separately added to the film formation apparatus capable of supplying two or more kinds of solutions described in the embodiment 2 (see FIG. 10).

In the constitution shown in FIG. 10, as described in the embodiment 2, the different solutions 4, 8 converted into mist may be simultaneously supplied to the substrate 2. The different solutions 4, 8 converted into mist may be separately supplied to the substrate 2 in a predetermined order. Also in these supply aspects, as described also in the embodiment 2, it is desired that the respective solutions 4, 8 are supplied toward the substrate 2 in the reaction vessel 1 from the solution containers 5, 9 through the different paths L1, L4.

In the constitution example of FIG. 10, as described in the embodiment 2, while ozone (or oxygen) is always supplied, the different solutions 4, 8 converted into mist may be separately supplied in a predetermined order. Alternatively, the different solutions 4, 8 converted into mist may be separately supplied in a predetermined order and, after temporarily stopping supply of the solutions 4, 8 every time supply of the solutions 4, 8 is switched, ozone (or oxygen) may be supplied (for example, supply of the solution 4→supply of ozone (or oxygen)→supply of the solution 8→supply of ozone (or oxygen)).

Herein, in any of the supply aspects described above, it is desired that the respective solutions 4, 8 and ozone (or oxygen) are supplied toward the substrate 2 in the reaction vessel 1 through the different paths L1, L2, L4.

Unlike in FIG. 10, a constitution capable of converting ozone (or oxygen) into plasma in the reaction vessel 1 may also be employed. In this case, in the film formation apparatus described in the embodiment 2, the plasma generator 13 is arranged in the reaction vessel 1.

While the present invention has been described in detail, the above description is for illustrative purpose in all aspects and it is not to be construed restrictively. It will be understood that non-illustrated innumerable modifications are possible which nevertheless are within the scope of the present invention.

1. A method of forming a metal oxide film, the method comprising:
(A) converting a solution comprising a metal into a mist;
(B) heating a substrate; and
(C) supplying the mist from (A) and ozone to a first main surface of the substrate from (B).

2. A method of forming a metal oxide film, the method comprising:
(V) converting a solution comprising a metal into a mist;
(W) supplying the mist from (V), and oxygen or ozone to a first main surface of a substrate; and
(X) irradiating the oxygen or the ozone with ultraviolet rays.

3. A method of forming a metal oxide film, the method comprising:
(V) converting a solution comprising a metal into a mist;
(W) supplying the mist from (V), and oxygen or ozone to a first main surface of a substrate; and
(X) converting the oxygen or the ozone into a plasma.

4. The method of forming a metal oxide film according to claim 2, wherein, in (W), the substrate is heated.

5. The method of forming a metal oxide film according to claim 1, wherein the metal is at least one selected from the group consisting of titanium, zinc, indium, and tin.

6. The method of forming a metal oxide film according to claim 5, wherein the solution further comprises at least one selected from the group consisting of boron, nitrogen, fluorine, magnesium, aluminum, phosphorus, chlorine, gallium, arsenic, niobium, indium and antimony.

7. The method of forming a metal oxide film according to claim 1, wherein
the converting (A) comprises converting two or more different solutions into a mist, and
the supplying (C) of the mist of the different solutions is carried out simultaneously or separately.

8. The method of forming a metal oxide film according to claim 1, wherein the supplying (C) of the mist of the solution and the ozone is carried out simultaneously or separately.

9. The method of forming a metal oxide film according to claim 2, wherein the supplying (W) of the mist of the solution and the oxygen or the ozone is carried out simultaneously or separately.

10. The method of forming a metal oxide film according to claim 1, wherein the supplying (C) of the mist of the solution and the ozone through is different paths.

11. The method of forming a metal oxide film according to claim 2, wherein the supplying (W) of the mist of the solution and the oxygen or the ozone is through different paths.

12. The method of forming a metal oxide film according to claim 1, wherein the supplying (C) of the mist of the solution and the ozone to the substrate is carried out under an atmospheric pressure.

13. The method of forming a metal oxide film according to claim 2, wherein the supplying (W) of the mist of the solution and the oxygen or the ozone to the substrate is carried out under an atmospheric pressure.

14. The method of forming a metal oxide film according to claim 1, wherein the supplying (C) of the mist of the solution and the ozone to the substrate is carried out under a reduced pressure environment.

15. The method of forming a metal oxide film according to claim 2, wherein the supplying (W) of the mist of the solution and the oxygen or the ozone to the substrate is carried out under a reduced pressure environment.

16. An apparatus for forming a metal oxide film by the method of claim 1, the apparatus comprising:
a reaction vessel;
a misting device;
a heating device; and
an ozone generator.

17. The method of forming a metal oxide film according to claim 3, wherein, in (W), the substrate is heated.

18. The method of forming a metal oxide film according to claim 2, wherein the metal is at least one selected from the group consisting of titanium, zinc, indium, and tin.

19. The method of forming a metal oxide film according to claim 3, wherein the metal is at least one selected from the group consisting of titanium, zinc, indium, and tin.

20. The method of forming a metal oxide film according to claim 18, wherein the solution further comprises at least one selected from the group consisting of boron, nitrogen, fluorine, magnesium, aluminum, phosphorus, chlorine, gallium, arsenic, niobium, indium, and antimony.

21. The method of forming a metal oxide film according to claim 19, wherein the solution further comprises at least one selected from the group consisting of boron, nitrogen, fluorine, magnesium, aluminum, phosphorus, chlorine, gallium, arsenic, niobium, indium, and antimony.

22. The method of forming a metal oxide film according to claim 2, wherein
the converting (V) comprises converting two or more different solutions into a mist, and
the supplying (W) of the mist of the different solutions is carried out simultaneously or separately.

23. The method of forming a metal oxide film according to claim 3, wherein
the converting (V) comprises converting two or more different solutions into a mist, and
the supplying (W) of the mist of the different solutions is carried out simultaneously or separately.

24. The method of forming a metal oxide film according to claim 3, wherein the supplying (W) of the mist of the solution and the oxygen or the ozone is carried out simultaneously or separately.

25. The method of forming a metal oxide film according to claim 3, wherein the supplying (W) of the mist of the solution and the oxygen or the ozone is through different paths.

26. The method of forming a metal oxide film according to claim 3, wherein the supplying (W) of the mist of the solution and the oxygen or the ozone to the substrate is carried out under an atmospheric pressure.

27. The method of forming a metal oxide film according to claim 3, wherein the supplying (W) of the mist of the solution and the oxygen or the ozone to the substrate is carried out under a reduced pressure environment.

28. An apparatus for forming a metal oxide film by the method of claim 2, the apparatus comprising: a reaction vessel; a misting device; a heating device; and an ultraviolet ray generator.

29. An apparatus for forming a metal oxide film by the method of claim 3, the apparatus comprising: a reaction vessel; a misting device; a heating device; and a plasma generator.
